(19) United States
(12) Patent Application Publication
(10) Pub. No.: US 2024/0274204 A1
(43) Pub. Date: Aug. 15, 2024

(54) OPERATION METHODS OF MEMORIES, MEMORIES, AND STORAGE SYSTEMS

(71) Applicant: Yangtze Memory Technologies Co., LTD., Wuhan (CN)

(72) Inventors: Wenhui Pei, Wuhan (CN); Yifan Li, Wuhan (CN); JunYao Zhu, Wuhan (CN); Tianyu Wang, Wuhan (CN); XueQing Huang, Wuhan (CN); ZhiLiang Xia, Wuhan (CN)

(21) Appl. No.: 18/324,001

(22) Filed: May 25, 2023

(30) Foreign Application Priority Data
Feb. 10, 2023 (CN) 202310117958.8

(51) Int. Cl. G11C 16/10; G11C 7/04; G11C 16/12

(52) U.S. Cl. CPC G11C 16/102; G11C 7/04; G11C 16/12

(57) ABSTRACT

Examples of the present application disclose an operation method of a memory, a memory, and a storage system. The method comprises: acquiring programming temperatures that are temperatures of memory cells to be programmed; performing first temperature compensation operation on a default incremental voltage of programming pulses to obtain a first incremental voltage of first memory cells to be programmed when the programming temperatures are within a first temperature range; and performing incremental step-pulse programming on the first memory cells according to the first incremental voltage. The examples of the present application can improve read margins of the memory cells, reduce reading errors, and have a smaller overall performance loss.

### CROSS-REFERENCE TO RELATED APPLICATION

This application claims priority to and the benefit of Chinese Patent Application 202310117958.8, filed on Feb. 10, 2023, which is hereby incorporated by reference in its entirety.

### TECHNICAL FIELD

The present disclosure relates to the field of semiconductors and, in particular, to an operation methods of memories, memories, and storage systems.

### BACKGROUND

A memory may perform various operations, such as reading, programming (writing) and erasing. How to operate the memory to improve the performance of the memory has become an urgent issue to be addressed.

### BRIEF DESCRIPTION OF THE DRAWINGS

The drawings to be used in the description of examples will be briefly introduced below in order to illustrate the technical solutions in the examples more clearly. The drawings described below are only examples. Those of ordinary skill in the art will readily understand that other examples in accordance with the examples described herein are possible.

FIG. 1 is a structural schematic diagram of a memory according to examples described herein;

FIG. 2 is a structural schematic diagram of a memory array in a memory according to examples described herein;

FIG. 3 is another structural schematic diagram of a memory array in a memory according to examples described herein;

FIG. 4 is a plot of threshold voltages versus the number of memory cells in a memory according to examples described herein;

FIG. 5 is an ESUM schematic diagram of memory cells in a memory at different programming temperatures according to examples described herein;

FIG. 6 is an ESUM schematic diagram of memory cells in a memory at different programming temperatures and under different operations according to examples described herein;

FIG. 7 is a tPROG schematic diagram of memory cells in a memory at different programming temperatures and under different operations according to examples described herein;

FIG. 8 is an IDS schematic diagram of memory blocks in a memory at different programming temperatures according to examples described herein;

FIG. 9 is an ESUM schematic diagram of memory blocks in a memory at different programming temperatures according to examples described herein;

FIG. 10 is a flow diagram of an operation method of a memory according to examples described herein;

FIG. 11 is an ESUM increasing rate schematic diagram of memory cells at different stages in a memory according to examples described herein;

FIG. 12 is a tPROG increasing amount schematic diagram of memory cells at different stages in a memory according to examples described herein;

FIG. 13 is an incremental voltage schematic diagram of memory cells in a memory according to examples described herein;

FIG. 14 is an ESUM schematic diagram at different programming temperatures of first memory cells at different stages in a memory according to examples described herein;

FIG. 15 is a tPROG schematic diagram at different programming temperatures of first memory cells at different stages in a memory according to examples described herein;

FIG. 16 is an incremental voltage schematic diagram at different programming temperatures of memory cells in a memory according to examples described herein;

FIG. 17 is an ESUM schematic diagram at different programming temperatures of memory cells in a memory according to examples described herein;

FIG. 18 is a tPROG schematic diagram at different programming temperatures of memory cells in a memory according to examples described herein; and

FIG. 19 is a structural schematic diagram of a storage system according to examples described herein.

### DETAILED DESCRIPTION

Specific structures and function details disclosed herein are merely representative, and are for the purpose of describing examples. However, the examples may be implemented specifically through many alternative forms, and should not be interpreted as being only limited to the examples set forth herein.

In the examples described herein, it is to be understood that the terms “center”, “lateral”, “upper”, “lower”, “left”, “right”, “vertical”, “horizontal”, “top”, “bottom”, “inner”, “outer”, etc. indicate orientation or position relationships that are based on the orientations or position relationships as shown in the examples, are only intended to facilitate description and to simplify the description, instead of indicating or implying the device or element indicated must have a specific orientation and be constructed and operated in a specific orientation, and thus cannot be understood as limiting. Furthermore, the terms “first” and “second” are only for the purpose of description, and cannot be construed as indicating or implying relative importance or implicitly indicating the number of indicated technical features. Thus, features defined by “first” and “second” may explicitly or implicitly include one or more of such features. In the description, “a plurality of” means two or more, unless otherwise stated. In addition, the term “comprise,” and any variants thereof are intended to cover non-exclusive “including.”

In the description, it should be noted that, unless otherwise specified and defined expressly, the terms “connected” and “connecting” should be understood broadly, which, for example, may be fixed connection, detachable connection, or integrated connection; may be either mechanical connection or electrical connection; may be either direct connection or indirect connection through intermediate media, and may be communication inside two elements. Those of ordinary skill in the art may understand the specific meanings of the above-mentioned terms in the examples according to specific conditions.

The terms as used herein are only used to describe the specific examples and are not intended to limit the examples. Unless otherwise indicated expressly in the context, “a,” “an” and “one” in a singular form are also intended to include plurality. It should also be understood that the terms “comprise” and/or “include,” as used herein, specify the presence of the stated feature, integer, step, operation, unit and/or component, and do not preclude the presence or addition of one or more of other features, integers, steps, operations, units, components, and/or a combination thereof.

Examples described herein provide operation methods of memories, memories, and storage systems.

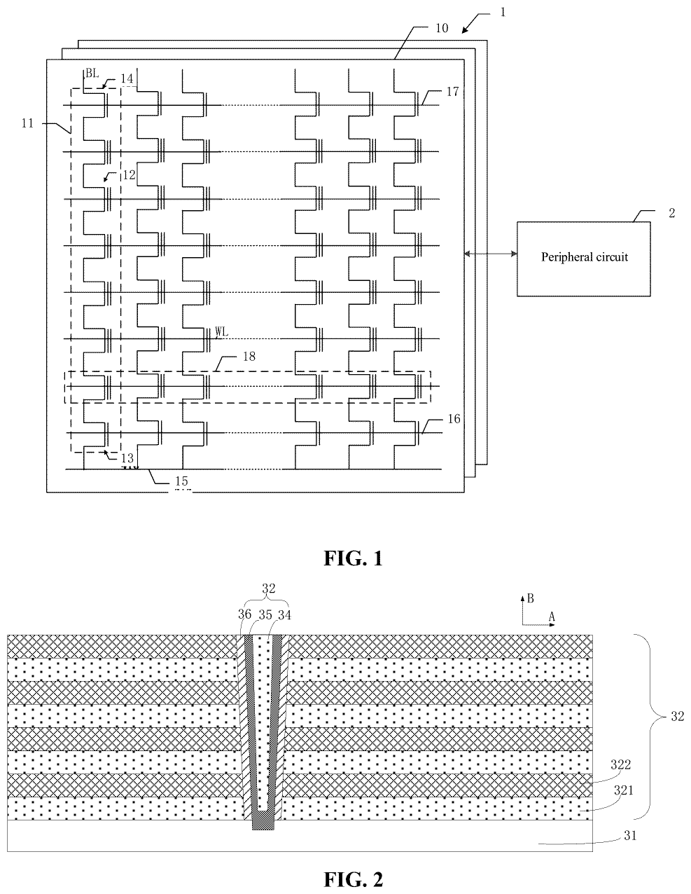

Referring to FIG. 1, which is a structural schematic diagram of a memory according to one example, the memory comprises a memory array 1, and a peripheral circuit 2 coupled to the memory array 1. The memory array 1 may be a non-volatile memory array which maintains its state in case of power failure.

The memory array 1 comprises a plurality of memory blocks 10 that are basic data units for erase operation. The memory blocks 10 comprise a plurality of memory strings 11 each comprising a plurality of memory cells 12 that are coupled in series and disposed in stacks. Each memory cell 12 may be either a “floating gate” type memory cell that includes a floating gate transistor, or a “charge trap” type memory cell that includes a charge trap transistor.

Each memory string 11 may be coupled to a source select transistor 13 (the source select transistor 13 coupled to an SSG line 16) at its source end, and to a drain select transistor 14 (the drain select transistor 14 coupled to a DSG line 17) at its drain end. The source select transistors 13 and the drain select transistors 14 may be configured to activate selected memory strings 11 during read and program (write) operations. In some implementations, the source select transistors 13 of the memory strings 11 in the same memory block are coupled through the same source line 15 (e.g., a common source line), i.e., all the memory strings 11 in the same memory block have an array common source. The drain select transistor 14 of each memory string 11 is coupled to a respective bit line BL from which data may be read or written via an output bus (not shown in the figure). The memory cells 12 of the adjacent memory strings 11 are coupled through word lines WL that select which row of the memory cells 12 is affected by read operation. In some implementations, each word line WL is coupled to a memory page 18 of the memory cells 12, which is the basic data unit for the program and read operations.

The peripheral circuit 2 may be coupled to the memory array 1 through the bit lines BL, the word lines WL, the source lines 15, the SSG lines 16 and the DSG lines 17. The peripheral circuit 2 may comprise any suitable analog, digital and hybrid signal circuit for facilitating the operations of the memory array 1 by applying and sensing voltage signals and/or current signals to and from each target memory cell 12 via the bit lines BL, the word lines WL, the source lines SL 15, the SSG lines 16 and the DSG lines 17. The peripheral circuit 2 may include various types of peripheral circuits formed using a metal-oxide-semiconductor (MOS) technology.

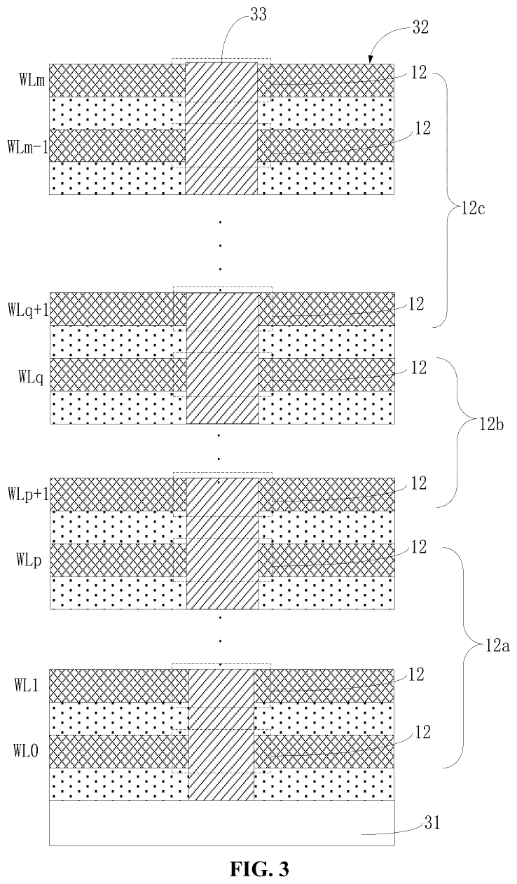

FIG. 2 is a sectional schematic diagram of the memory array 1. As shown in FIG. 2, the memory array 1 comprises a substrate 31 and a stack structure 32 positioned on the substrate 31. The substrate 31 may comprise monocrystalline silicon, polycrystalline silicon, monocrystalline germanium, a group III-V compound semiconductor material, a group II-VI compound semiconductor material, and other semiconductor materials. The stack structure 32 may comprise insulation layers 321 and gate layers 322 that are stacked alternately along a direction A. The number of stacked layers in the stack structure 32 may be 32, 64, 128, etc., which is not defined specifically herein. The material of the insulation layers 321 may include any one of materials, such as silicon oxide, silicon nitride, silicon oxynitride, doped silicon oxide, organosilicate glass, and the like. The material of the gate layers 322 may include at least one of tungsten, cobalt, copper, aluminum, doped polycrystalline silicon, metal silicide and the like.

The gate layers 322 may comprise control gates of the memory cells 12, gates of the source select transistors 13, or gates of the drain select transistors 14. The gate layers 322 may extend along the direction A as word lines connected with the control gates of the memory cells 12, SSG lines 16 connected with the gates of the source select transistors 13, or DSG lines 17 connected with the drain select transistors 14. The direction A is perpendicular to a stack direction of the stack structure 32.

The memory array 1 further comprises a memory channel structure 33 that penetrates through the stack structure 32 along a direction B. The direction B is consistent with the stack direction of the stack structure 32. The memory channel structure 33 may comprise a channel filling layer 34, a channel layer 35 disposed around the channel filling layer 34, and a memory film 36 disposed around the channel layer 35. The memory film 36 may comprise a tunneling layer (not shown in the figure) disposed around the channel layer 35, a memory layer (not shown in the figure) disposed around the tunneling layer, and a barrier layer (not shown in the figure) disposed around the memory layer. The barrier layer and the tunneling layer may include silicon oxide, silicon oxynitride or any combination thereof; the memory layer may include silicon nitride, silicon oxynitride, silicon or any combination thereof; and the channel layer 35 includes silicon, such as amorphous silicon, polycrystalline silicon, or monocrystalline silicon. The memory film 36 and the channel layer 35 may be formed using one or more thin film deposition processes such as ALD, CVD, PVD, any other suitable processes or any combination thereof. In one example, the memory film 36 may include a composite layer of silicon oxide/silicon nitride/silicon oxide (ONO).

The memory channel structure 33 penetrates through the stack structure 32 to form a plurality of memory cells 12 on the substrate 31 that are disposed in stacks along the direction B, and the gate layers connected with the memory cells 12 constitute word lines WL. As shown in FIG. 3, the memory array may comprise a plurality of memory cells 12 sequentially disposed in stacks along the direction B, and each memory cell 12 is correspondingly connected with one word line WL, and the word lines are numbered as WL0, . . . , WLp, WLp+1, . . . , WLq, WLq+1, . . . , WLm sequentially from the bottom to the top of the memory strings 11, where p, q and m are all positive integers, and m>q>p.

The principle of storing information in memory is to change threshold voltages of memory cells by changing the amount of charge stored in storage media to achieve the purpose of storing the information. For example, a memory cell in an erase data state may be considered as having no electron in its storage medium, thus its threshold voltage is less than the read voltage, and the information stored therein is considered to be 1. However, for a memory cell in a stored data state, there are no electrons in the storage medium, and its threshold voltage is generally greater than the read voltage, and the information stored therein is considered to be 0.

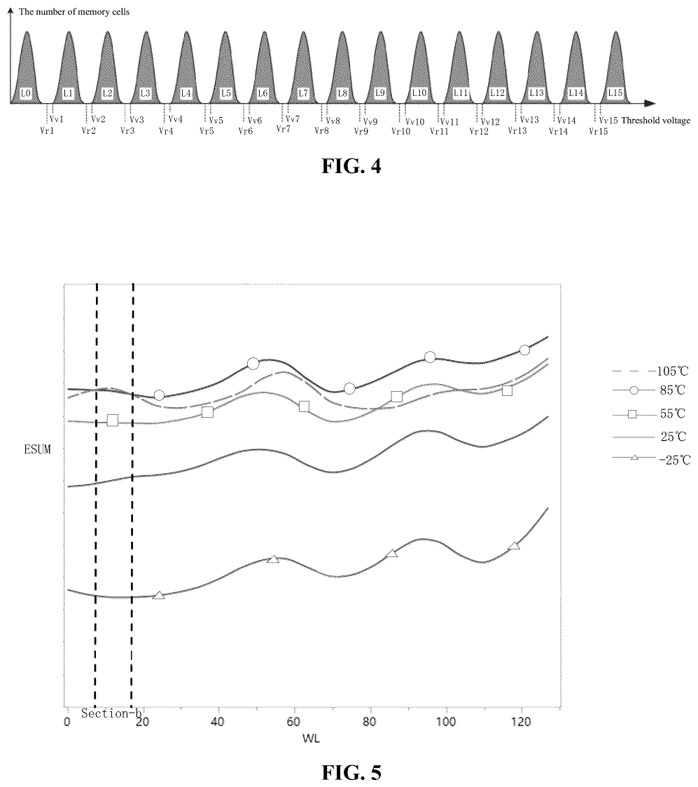

The memory cells may store multiple bits of information, which is achieved by designing a plurality of sets of threshold voltages and further programming the memory cells into multiple data states each having different threshold voltages. FIG. 4 is a plot of threshold voltages versus the number of memory cells, and illustrates an example threshold voltage distribution of a memory array when each memory cell stores four bits of data. FIG. 4 illustrates 16 threshold voltage distributions, which correspond to the following 16 threshold voltage distributions: E (also referred to as L0), L1, L2, L3, L4, L5, L6, L7, L8, L9, L10, L11, L12, L13, L14 and L15, and the threshold voltages increase sequentially. Likewise, the threshold voltage distribution E corresponds to an erase data state; the threshold voltage distributions L1, L2, L3, L4, L5, L6, L7, L8, L9, L10, L11, L12, L13, L14 and L15 correspond to a program data state; and for a data state N, the data state N has a higher threshold voltage than a data state N−1 and a lower threshold voltage than a data state N+1. In some examples, the memory cells store four bits of data; specifically, the erased memory cells may store data 1111, and the memory cells programmed to L1, L2, L3, L4, L5, L6, L7, L8, L9, L10, L11, L12, L13, L14 and L15 data states may store the data 1110, 1101, 1100, 1011, 1010, 1201, 1000, 0111, 0110, 0101, 0100, 0011, 0010, 0001 and 0000 sequentially. FIG. 4 further illustrates 15 read reference voltages Vr1, Vr2, Vr3, Vr4, Vr5, Vr6, Vr7, Vr8, Vr9, Vr10, Vr11, Vr12, Vr13, Vr14 and Vr15 for reading data from the memory cells, and the specific reading procedure may be: testing, e.g., performing sensing operation whether a threshold voltage of a given memory cell is higher or lower than the 15 read reference voltages, and the storage system may determine the data state in which the memory cell is.

FIG. 4 further illustrates 15 verify reference voltages Vv1, Vv2, Vv3, Vv4, Vv5, Vv6, Vv7, Vv8, Vv9, Vv10, Vv11, Vv12, Vv13, Vv14 and Vv15, which may also be referred to as verify target voltages. When the memory cells are programmed to the data state L1, these memory cells are determined whether to have a threshold voltage greater than or equal to Vv1. When the memory cells are programmed to the data state L2, the memory cells are determined whether to have a threshold voltage greater than or equal to Vv2, and so on; the memory cells are verified whether to have a threshold voltage greater than or equal to Vv3, Vv4, Vv5, Vv6, Vv7, Vv8, Vv9, Vv10, Vv11, Vv12, Vv13, Vv14 and Vv15 sequentially to determine whether they are correspondingly programmed to L3, L4, L5, L6, L7, L8, L9, L10, L11, L12, L13, L14 and L15. In one implementation referred to as full sequence programming, the memory cells may be directly programmed from the erase data state L0 to any one of the program data states L1-L15. For example, a group of memory cells to be programmed may be erased first such that all the memory cells in the group are in the erase data state L0. Then, the memory cells are directly programmed to one of the data states L1, L2, L3, L4, L5, L6, L7, L8, L9, L10, L11, L12, L13, L14 and L15 using a programming procedure. For example, although some memory cells are being programmed from the data state L0 to the data state L1, other memory cells are being programmed from the data state L0 to the data state L2 and/or from the data state L0 to the data state L3, and so on. The arrow in FIG. 4 represents the full sequence programming. In addition to the full sequence programming, the technology as described in the present application may also be used with other types of programming, including but not limited to, multi-level programming/multi-phase programming.

Generally speaking, during the verify operation and the read operation, the selected word lines are connected to a voltage which is a reference signal, and the level of the voltage is specified for each read operation (e.g., see the read reference voltage of FIG. 4) or verify operation (e.g., see the verify reference voltage of FIG. 4) to determine whether the threshold voltages of related memory cells have reached this level. After this voltage is applied to the word lines, conduction currents of the memory cells are measured to determine whether the memory cells are turned on (whether there are conduction currents, and the values of the currents are measured) in response to the voltage applied to the word lines. If the conduction currents are measured as being greater than a specific value, then it is assumed that the memory cells are turned on and the voltage applied to the word lines is greater than the threshold voltages of the memory cells. If the conduction currents are not measured as being greater than a specific value, then it is assumed that the memory cells are not turned on and the voltage applied to the word lines is not greater than the threshold voltages of the memory cells. During the reading or verifying procedure, the unselected memory cells are provided with one or more pass voltages at their control gates, which may be referred to as bypass voltages, such that these memory cells will operate as pass gates to conduct currents regardless of whether these memory cells are programmed or erased.

This example utilizes a Margin (a read margin) to characterize the voltage interval between the threshold voltage distributions corresponding to two adjacent data states that can be used to read data on the memory cells in one of the data states. For example, a first Margin may refer to a voltage interval between the threshold voltage distribution corresponding to the memory cells in the erased state and the threshold voltage distribution corresponding to the memory cells in the first program data state that can be used to read the data on the memory cells in the erased state, and this voltage interval may also be referred to as E0. For example, as shown in FIG. 4, in a QLC type of memory cell, a voltage interval between a lower tail of the threshold voltage distribution corresponding to the data state L0 and a voltage Vr1 is the first Margin E0. It should be known to those skilled in the art that, for the QLC type of memory cell, two Margins are present between every two adjacent data states. The first Margin is used to read the data on the memory cell in the first data state, and the second Margin is used to read the data on the memory cell in the second data state. For instance, the Margin between the data state L0 and the data state L1 includes E0 and E1, and E1 is a voltage interval between the voltage Vr1 and an upper tail of the threshold voltage distribution corresponding to the data state L1. In some examples, for the QLC type of memory cell, the overall Margins may include a total of 30 Margins: E0, E1, . . . , E29, which may be written as ESUM=E0+E1+ . . . +E29.

The memory cells may be programmed at different temperatures, and the Margins of the memory cells after being programmed at different temperatures have very large differences, such that the ESUMs have very large differences. In addition, due to the process differences such as channel hole (the memory channel structure 33 in FIG. 2 is formed in a channel hole) fabrication, etc. (e.g., the diameter of the channel hole at the lower portion of the memory array is smaller, while the diameter of the channel hole at the upper portion of the memory array is larger), the Margins and ESUMs of the memory cells in different regions of the memory array after being programmed at the same temperature also have large differences. However, the smaller the Margins are, the smaller the ESUMs are, which easily results in reading errors.

In some examples, in order to address the influence caused by the process differences, ISPP (incremental step-pulse programming) operation is performed on the memory cells, i.e., voltages of programming pulses are gradually increased from a starting voltage to a target voltage based on a step voltage (i.e., an incremental voltage). This programming method can improve the uniformity of overall ESUMs of the memory array; however, the ESUMs still have large differences at different temperatures.

As shown in FIG. 5, the ISPP operation is performed on the memory blocks in a fresh stage at −25° C., 25° C., 55° C., 85° C. and 105° C. respectively, and the ESUM of the memory cells coupled with each word line after being programmed is detected, where the fresh stage means that the number of uses of the memory cells in the memory array is less than a preset number (i.e., the memory cells are at the initial stage of life, and the preset number may be 1). The abscissa in FIG. 5 represents word lines WL (the word lines WL are numbered from the bottom of the memory block), and the ordinate represents ESUMs. As can be seen from FIG. 5, the uniformity of the overall ESUMs of the memory block is improved, but the ESUMs of the memory block at different temperatures still have large differences, and the ESUMs of the memory cells in a Section-b region in the memory block (e.g., in a partial region at the lower portion of the memory array, e.g., the memory cells corresponding to the word lines WL numbered from 8 to 18) at a low temperature (e.g., −25° C.) are poor.

In some other examples, in order to address the influence caused by the temperature differences, the incremental voltage in the above-mentioned ISPP operation is compensated to reduce the incremental voltage. For example, the incremental voltage in the above-mentioned ISPP operation is a default incremental voltage default, and after compensation is default-50 mv. Since the polycrystalline silicon channel has a low electron mobility at a low temperature, this programming method can improve the threshold voltage width after programming at the low temperature, and further improve the Margin and ESUM at the low temperature; however, the overall tPROG (total time required for programming) loss of the memory block is large.

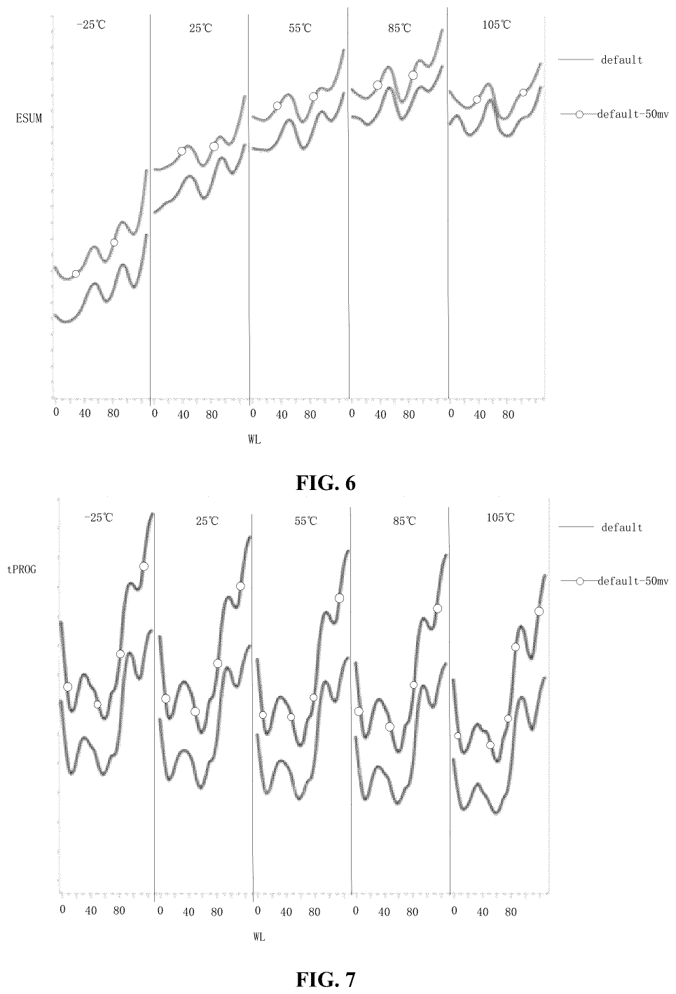

As shown in FIGS. 6 and 7, the first ISPP operation and second ISPP operation are performed respectively on the memory block in the fresh stage at −25° C., 25° C., 55° C., 85° C. and 105° C., and the ESUM and tPROG of the memory cell coupled with each word line after operation is detected. The incremental voltage in the first ISPP operation is the default incremental voltage default, and the second ISPP operation compensates for the default incremental voltage default such that the incremental voltage in the second ISPP operation is default-50 mv. The abscissa in FIG. 6 represents word lines WL (the word lines WL are numbered from the bottom of the memory block), and the ordinate represents ESUMs. As can be seen from FIG. 6, at different temperatures, the ESUMs of the memory block after the second ISPP operation are all greater than the ESUMs after the first ISPP operation. The abscissa in FIG. 7 represents word lines WL (the word lines WL are numbered from the bottom of the memory block), and the ordinate represents tPROGs. As can be seen from FIG. 7, at different temperatures, the tPROGs of the memory block after the second ISPP operation are all greater than the tPROGs after the first ISPP operation.

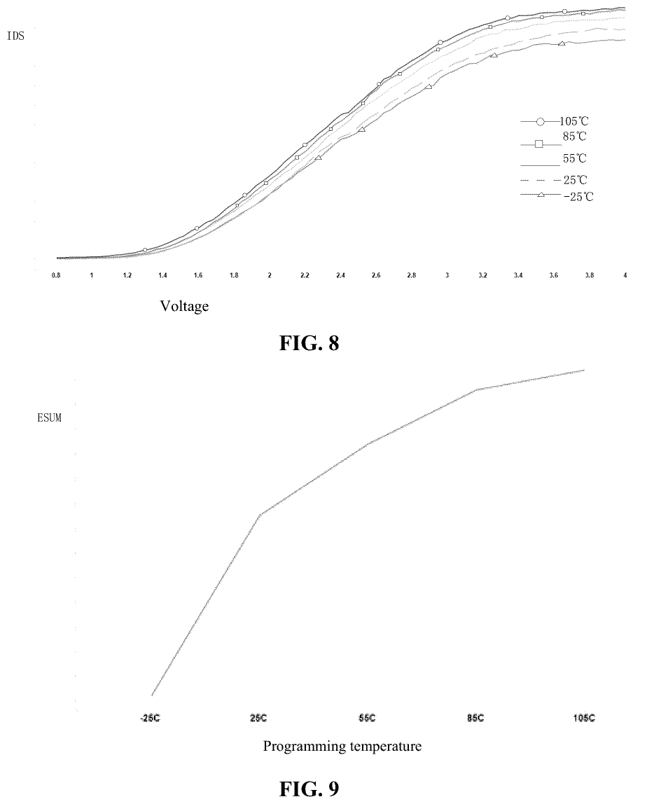

Although the above-mentioned second ISPP operation compensates for the default incremental voltage, the current subthreshold slope at low temperatures is still very large, and therefore, the ESUM of the memory block is still very small at low temperatures. As shown in FIGS. 8 and 9, the second ISPP operation is performed on the memory block in the fresh stage at −25° C., 25° C., 55° C., 85° C. and 105° C. The abscissa in FIG. 8 represents voltages applied to word lines WL, and the ordinate represents channel currents (IDS). As can be seen from FIG. 8, after the second ISPP operation is performed on the memory block, the current subthreshold slope is still very large at low temperatures (e.g., −25° C.). The abscissa in FIG. 9 represents programming temperatures, and the ordinate represents ESUMs. As can be seen from FIG. 9, after the second ISPP operation is performed on the memory block, the ESUMs are still low at low temperatures (e.g., −25° C.).

Examples described herein provide operation methods of memories in order to address the influence caused by the above-mentioned process differences and temperature differences at the same time.

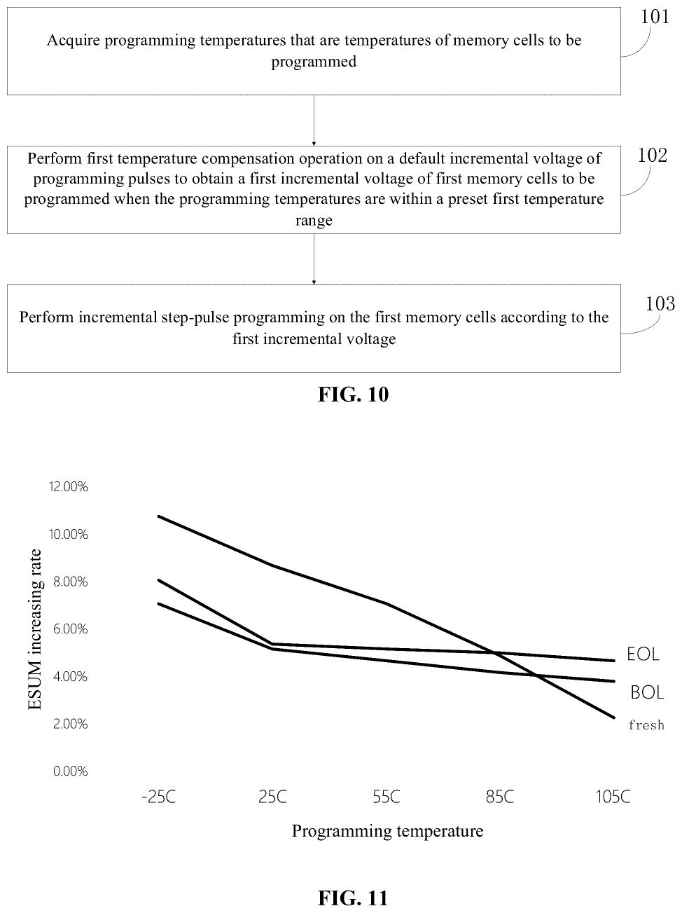

The example of FIG. 10 shows a flow diagram of an operation method of a memory according to examples described herein.

As shown in FIG. 10, the examples described herein provide an operation method of a memory or memories. The method includes 101 to 103, according to one example, as follows:

In FIG. 10, 101 includes acquiring programming temperatures that are temperatures of memory cells to be programmed.

The programming temperatures are mainly environment temperatures, i.e., the environment temperatures when performing programming on the memory cells are the programming temperatures. In some implementations, a temperature sensor may be disposed within the memory to measure the environment temperatures through the temperature sensor in order to acquire the programming temperatures.

According to the example of FIG. 10, 102 includes performing first temperature compensation operation on a default incremental voltage of programming pulses to obtain a first incremental voltage of first memory cells to be programmed when the programming temperatures are within a preset first temperature range.

The first memory cells are partial memory cells in the memory array, and are memory cells greatly affected by the process differences, i.e., after being programmed under the same condition, ESUMs of the first memory cells are smaller than ESUMs of other memory cells in the memory array. In some implementations, the first memory cells are located at a lower portion of the memory array, i.e., the first memory cells are disposed close to a substrate. As shown in FIG. 3, the first memory cells 12a may include memory cells 12 corresponding to word lines WL0 to WLp. As shown in FIG. 5, the first memory cells 12a may also be memory cells in the Section-b region.

The first temperature range is a temperature range having great influence on the programming of the memory cells, i.e., the ESUMs of the memory cells after being programmed within the first temperature range are smaller than those after being programmed within other temperature ranges. The first temperature range may be a temperature range of relatively low temperatures, e.g., −25° C. to 0° C., or −25° C. to 25° C., etc.

The programming pulses are programming voltages applied to the memory cells during programming, and a plurality of programming pulses are applied to the memory cells sequentially in an ISPP operation. The default incremental voltage is the incremental voltage in the first ISPP operation in the above-mentioned example, i.e., voltage differences of two adjacent programming pulses in the first ISPP operation in the above-mentioned example.

When the programming temperatures are within the first temperature range, the first memory cells are affected by dual influences of processes and temperatures, and therefore, for the programming of the first memory cells, the first temperature compensation operation may be performed on the default incremental voltage to reduce the default incremental voltage to obtain a first incremental voltage of the first memory cells, i.e., the first incremental voltage is less than the default incremental voltage.

Specifically, performing the first temperature compensation operation on a default incremental voltage of the programming pulses to obtain a first incremental voltage of the first memory cells to be programmed in the 101, comprises:
determining a compensation voltage of the first memory cells; and
subtracting the compensation voltage from the default incremental voltage to obtain the first incremental voltage of the first memory cells.

The compensation voltage is a voltage for compensating for the default incremental voltage, and the first incremental voltage of the first memory cells may be obtained by subtracting the compensation voltage of the first memory cells from the default incremental voltage. For example, the default incremental voltage is step, the compensation voltage of the first memory cells within the first temperature range is a1, and the first incremental voltage of the first memory cells within the first temperature range is step-a1.

According to one example, 103 includes performing incremental step-pulse programming on the first memory cells according to the first incremental voltage.

When the programming temperatures are within the first temperature range, the ISPP operation is performed on the first memory cells, and the incremental voltage in this ISPP operation is the first incremental voltage step-a1. For example, in the ISPP operation of the first memory cells within the first temperature range, a voltage of a first programming pulse is P11, a voltage of a second programming pulse is P12=P11+(step-a1), a voltage of a third programming pulse is P13=P12+(step-a1), and so on, until the voltage of the programming pulse is increased to a target voltage.

The memory cells may be divided into multiple stages according to the number of uses, such as a fresh stage, a BOL stage and an EOL stage. The fresh stage means that the number of uses of the memory cells is less than a preset number (i.e., the memory cells are at the initial stage of life, and the preset number may be 1). The BOL stage means that the number of uses of the memory cells is greater than the preset number and less than a threshold number (i.e., the memory cells are at the middle stage of life). The EOL stage means that the number of uses of the memory cells is greater than the threshold number (i.e., the memory cells are at the end stage of life).

When the programming temperatures are within the first temperature range, the compensation voltage of the first memory cells when the number of uses is less than the preset number are less than the compensation voltage when the number of uses is greater than the preset number. That is to say, the compensation voltage of the first memory cells in the fresh stage is less than the compensation voltage thereof in the BOL and EOL stages.

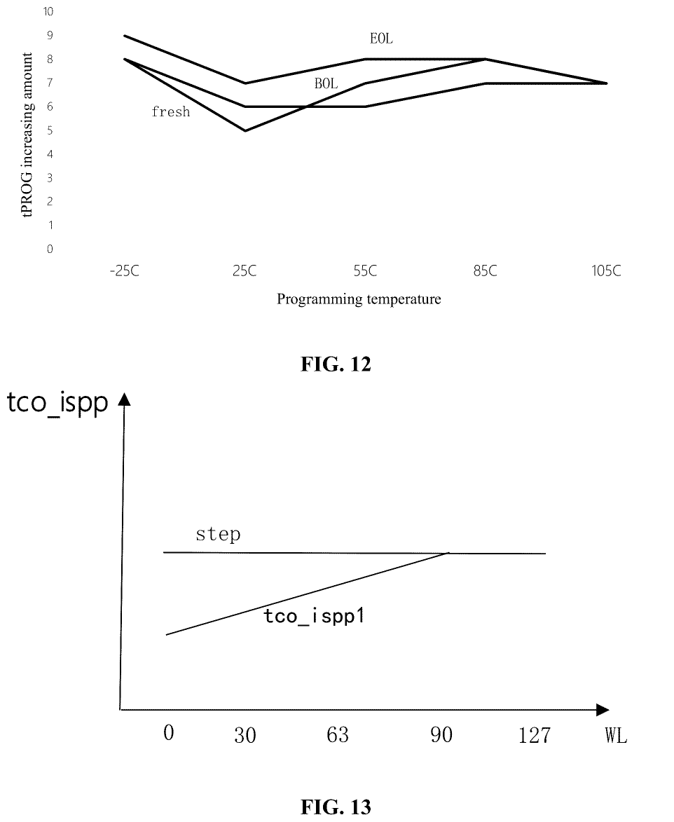

As shown in FIGS. 11 and 12, when the programming temperatures are −25° C., 25° C., 55° C., 85° C. and 105° C., the ISPP operation is performed on the first memory cells in the fresh stage, the BOL stage and the EOL stage respectively (the compensation voltages are the same, i.e., the incremental voltages are all the first incremental voltage), and ESUM increasing rates and tPROG increasing amounts of the first memory cells after being programmed are detected. The abscissa in FIG. 11 represents programming temperatures, and the ordinate represents ESUM increasing rates. As can be seen from FIG. 11, at low temperatures (e.g., −25° C.), the ESUM increasing rates corresponding to the first memory cells in the fresh stage are the greatest. The abscissa in FIG. 12 represents programming temperatures, and the ordinate represents tPROG increasing amounts. As can be seen from FIG. 12, at low temperatures (e.g., −25° C.), the tPROG increasing amounts corresponding to the first memory cells in the fresh stage are the smallest. As can be seen, when the compensation voltages are the same, the first memory cells in the fresh stage have the best improvement effect and smallest tPROG loss. That is to say, the compensation voltage of the first memory cells in the fresh stage is less than the compensation voltages thereof in the BOL and EOL stages, and the same improvement effect can be achieved.

For other memory cells (other memory cells in the memory array except the first memory cells), in order to further reduce an overall performance loss of the memory, the ISPP operation may be performed on the other memory cells according to other incremental voltages.

For second memory cells, the second memory cells are less affected by the processes than the first memory cells, i.e., after being programmed under the same conditions, the ESUMs of the second memory cells are greater than those of the first memory cells. In some implementations, the second memory cells are located at an upper portion of the memory array, with respect to positions of the first memory cells, i.e., the second memory cells are located on a side of the first memory cells facing away from the substrate. The number of the second memory cells is at least one. As shown in FIG. 3, the second memory cells 12b may be memory cells corresponding to word lines WLp+1 to WLq.

In the first implementation, for the programming of the second memory cells, the compensation operation may not be performed on the default incremental voltage, i.e., the incremental voltage of the second memory cells within the first temperature range is the default incremental voltage step. That is to say, when the programming temperatures are within the first temperature range, in the memory array, the default incremental voltages of other memory cells may not be compensated for during programming, except that the default incremental voltage of the first memory cells is required to be compensated for during programming.

In the second implementation, the method further comprises:
performing second temperature compensation operation on the default incremental voltage to obtain a second incremental voltage of second memory cells to be programmed when the programming temperatures are within the first temperature range, a compensation voltage of the second temperature compensation operation being less than that of the first temperature compensation operation; and
performing incremental step-pulse programming on the second memory cells according to the second incremental voltage.

When the programming temperatures are within the first temperature range, for the programming of the second memory cells, second temperature compensation operation may be performed on the default incremental voltage to reduce the default incremental voltage to obtain the second incremental voltage of the second memory cells, i.e., the second incremental voltage is less than the default incremental voltage. Specifically, a compensation voltage a2 of the second memory cells is set, the second incremental voltage step-a2 of the second memory cells may be obtained by subtracting the compensation voltage a2 of the second memory cells from the default incremental voltage step. Since the second memory cells are less affected by the processes than the first memory cells, the compensation voltage a2 of the second temperature compensation operation are less than the compensation voltage a1 of the first temperature compensation operation, i.e., a2<a1.

For example, in the ISPP operation of the second memory cells within the first temperature range, a voltage of a first programming pulse is P21, a voltage of a second programming pulse is P22=P21+(step-a2), a voltage of a third programming pulse is P23=P22+(step-a2), and so on, until the voltage of the programming pulse is increased to a target voltage.

Optionally, the method further comprises:
performing incremental step-pulse programming on third memory cells to be programmed according to the default incremental voltage when the programming temperatures are within the first temperature range.

The third memory cells may include other memory cells in the memory array besides the first memory cells and the second memory cells. The third memory cells are less affected by the processes than the second memory cells, i.e., after being programmed under the same conditions, the ESUMs of the third memory cells are greater than those of the second memory cells. The third memory cells are located at the upper portion of the memory array, i.e., the third memory cells are located on a side of the second memory cells facing away from the substrate. The number of the third memory cells is at least one. As shown in FIG. 3, the third memory cells 12c may be memory cells corresponding to the word lines WLq+1 to WLm.

When the programming temperatures are within the first temperature range, for the programming of the third memory cells, the compensation operation may not be performed on the default incremental voltage, i.e., the incremental voltage of the third memory cells is the default incremental voltage step. That is to say, in the memory array, the default incremental voltages of other memory cells may not be compensated for during programming, except that the default incremental voltages of the first memory cells and the second memory cells are required to be compensated for during programming.

For example, in the ISPP operation of the third memory cells within the first temperature range, a voltage of a first programming pulse is P31, a voltage of a second programming pulse is P32=P21+step, a voltage of a third programming pulse is P33=P32+step, and so on, until the voltage of the programming pulse is increased to a target voltage.

It should be noted that the second memory cells and the third memory cells may also have other memory cells (e.g., fourth memory cells) therebetween. For the programming of the fourth memory cells, the compensation operation may be performed on the default incremental voltage to reduce the default incremental voltage to obtain a third incremental voltage of the fourth memory cells. Specifically, a compensation voltage a3 of the fourth memory cells is set, and the third incremental voltage step-a3 of the fourth memory cells may be obtained by subtracting the compensation voltage a3 of the fourth memory cells from the default incremental voltage step. The compensation voltage a3 of the fourth memory cells are less than the compensation voltage a2 of the second memory cells, and the closer to the third memory cells, the smaller the compensation voltage of the fourth memory cells.

In some implementations, the compensation voltages of different memory cells within the first temperature range may be set proportionally. For example, the ratio of the compensation voltages of the first memory cells, the second memory cells and the fourth memory cells may be 5:3:1, i.e., a1:a2:a3=5:3:1.

When the programming of the memory cells includes coarse programming and fine programming, the coarse programming may be first performed on the memory cells, and then the fine programming is performed on the memory cells. The coarse programming and the fine programming are both ISPP. The incremental voltage in the coarse programming may be different from that in the fine programming. When the programming temperatures are within the first temperature range, the incremental voltages of at least one of the coarse programming and the fine programming are compensated incremental voltages to improve the Margin and reduce the tPROG losses of the memory cells to the greatest extent. Specifically, for the first memory cells, the incremental voltages of at least one of the coarse programming and the fine programming are the first incremental voltage; for the second memory cells, the incremental voltages of at least one of the coarse programming and the fine programming are the second incremental voltage; and for the fourth memory cells, the incremental voltages of at least one of the coarse programming and the fine programming are the third incremental voltage.

In some implementations, the farther the memory cells are away from the substrate, the smaller the compensation voltage of the memory cells is, and the larger the incremental voltage is. As shown in FIG. 13, the abscissa represents word lines WL (the word lines WL are numbered from the bottom of the memory block), and the ordinate represents incremental voltage tco_ispp. The larger the numbers of the word lines WL are, the smaller the compensation voltage of the memory cells corresponding to the word lines WL is, and the larger the incremental voltage tco_ispp1 is. When the compensation voltage of the memory cells is 0, the incremental voltage tco_ispp1 of the memory cells is the default incremental voltage step. For example, the compensation voltage of the memory cells corresponding to the word lines WL numbered from 0 to 90 is getting smaller and smaller, and the incremental voltage tco_ispp1 is getting larger and larger; the compensation voltage of the memory cells corresponding to the word lines WL numbered from 91 to 127 is 0, and the incremental voltage tco_ispp1 is the default incremental voltage step.

When the programming temperatures are within other temperature ranges (i.e., outside the first temperature range), in order to further reduce the overall performance loss of the memory array, the ISPP operation may be performed on the memory cells according to other incremental voltages.

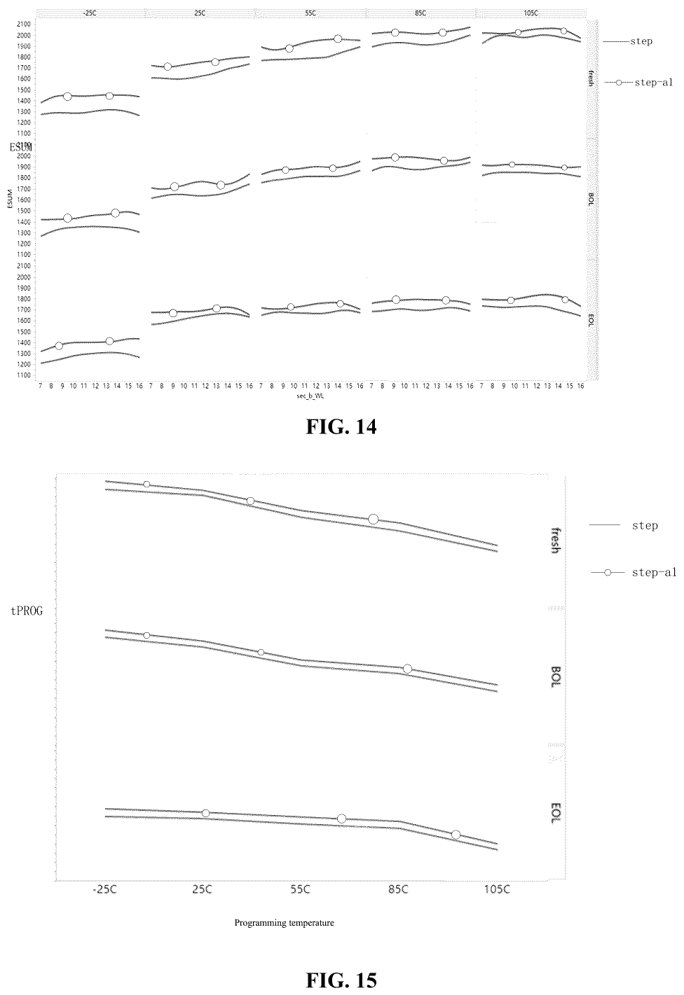

As shown in FIGS. 14 and 15, when the programming temperatures are −25° C., 25° C., 55° C., 85° C. and 105° C., the first ISPP operation and the third ISPP operation are performed on the first memory cells in the fresh stage, the BOL stage and the EOL stage respectively, and the ESUMs and tPROGs of the first memory cells after being programmed are detected. The incremental voltage in the first ISPP operation is the default incremental voltage step, and the incremental voltage in the second ISPP operation is the first incremental voltage step-a1.

The abscissa in FIG. 14 represents word lines sec_b_WL corresponding to the first memory cells, and the ordinate represents ESUMs. As can be seen from FIG. 14, at different temperatures, the ESUMs of the first memory cells at different stages after the third ISPP operation are all improved as compared with the ESUMs after the first ISPP operation, and the lower the programming temperatures are, the greater the improvements of the ESUMs are. The abscissa in FIG. 15 represents programming temperatures, and the ordinate represents tPROGs. As can be seen from FIG. 15, at different temperatures, the tPROGs of the first memory cells at each stage after the third ISPP operation have no obvious change as compared with those after the first ISPP operation (the tPROGs at different temperatures all have very small increase).

As can be seen, in this example, the improvement effect of the ESUMs is the best when the programming temperatures of the first memory cells are low temperatures, while the ESUMs are basically unaffected at high temperatures. Therefore, when the programming temperatures are within other temperature ranges (i.e., outside the first temperature range), the ISPP operation may be performed on the memory cells according to other incremental voltages.

Optionally, the method further comprises:
performing third temperature compensation operation on the default incremental voltage to obtain a third incremental voltage of the first memory cells when the programming temperatures are within a preset second temperature range, a compensation voltage of the third temperature compensation operation being less than that of the first temperature compensation operation, temperatures in the second temperature range being higher than those in the first temperature range; and
performing incremental step-pulse programming on the first memory cells according to the third incremental voltage.

The second temperature range has a smaller influence on the programming of the memory cells than the first temperature range, i.e., as compared with the first temperature range, the ESUMs of the memory cells are greater after being programmed within the second temperature range. Temperatures in the second temperature range are higher than those in the first temperature range, e.g., the second temperature range is 25° C. to 55° C., etc.

When the programming temperatures are within the second temperature range, for the programming of the first memory cells, third temperature compensation operation may be performed on the default incremental voltage to reduce the default incremental voltage to obtain the third incremental voltage of the first memory cells, i.e., the third incremental voltage is less than the default incremental voltage. Specifically, a compensation voltage b1 of the first memory cells within the second temperature range is set, and the third incremental voltage step-b1 of the first memory cells may be obtained by subtracting the compensation voltage b1 of the first memory cells from the default incremental voltage step. Since the first memory cells are less affected by the temperatures within the second temperature range, the compensation voltage b1 of the third temperature compensation operation are less than the compensation voltage a1 of the first temperature compensation operation, i.e., b1<a1.

For example, in the ISPP operation of the first memory cells within the second temperature range, a voltage of a first programming pulse is P41, a voltage of a second programming pulse is P42=P41+(step-b1), a voltage of a third programming pulse is P43=P42+(step-b1), and so on, until the voltage of the programming pulse is increased to a target voltage.

When the programming temperatures are within the second temperature range, for the programming of the second memory cells, the temperature compensation operation may be performed on the default incremental voltage. Specifically, a compensation voltage b2 of the second memory cells is set, and the incremental voltage step-b2 of the second memory cells may be obtained by subtracting the compensation voltage b2 of the second memory cells from the default incremental voltage step, b2<b1.

For example, in the ISPP operation of the second memory cells within the second temperature range, a voltage of a first programming pulse is P51, a voltage of a second programming pulse is P52=P51+(step-b2), a voltage of a third programming pulse is P53=P52+(step-b2), and so on, until the voltage of the programming pulse is increased to a target voltage.

When the programming temperatures are within the second temperature range, for the programming of the third memory cells, the temperature compensation operation may not be performed on the default incremental voltage, i.e., the incremental voltage of the third memory cells is the default incremental voltage step.

For example, in the ISPP operation of the third memory cells within the second temperature range, a voltage of a first programming pulse is P61, a voltage of a second programming pulse is P62=P61+step, a voltage of a third programming pulse is P63=P62+step, and so on, until the voltage of the programming pulse is increased to a target voltage.

Optionally, the method further comprises:
performing incremental step-pulse programming on the first memory cells according to the default incremental voltage when the programming temperatures are within a preset third temperature range, temperatures in the third temperature range being higher than those in the first temperature range.

The third temperature range has a smaller influence on the programming of the memory cells than the first temperature range, i.e., as compared with the first temperature range, the ESUMs of the memory cells are greater after being programmed within the third temperature range. In some implementations, temperatures in the third temperature range are higher than those in the second temperature range, e.g., the third temperature range is 85° C. to 105° C., etc.

When the programming temperatures are within the third temperature range, for the programming of the first memory cells, the compensation operation may not be performed on the default incremental voltage, i.e., the incremental voltage of the first memory cells is the default incremental voltage step. When the programming temperatures are within the third temperature range, for the programming of the second memory cells and the third memory cells, the compensation operation may not be performed on the default incremental voltage, i.e., the incremental voltages of the second memory cells and the third memory cells are all the default incremental voltage step. That is to say, when the programming temperatures are within the third temperature range, the incremental voltages of the memory cells in the memory array are all the default incremental voltage step.

It should be noted that, the second temperature range and the third temperature range may further have other temperature ranges (e.g., a fourth temperature range) therebetween, and temperatures in the fourth temperature range are higher than those in the second temperature range and lower than those in the third temperature range. When the programming temperatures are within the fourth temperature range, for the programming of the first memory cells, the compensation operation may be performed on the default incremental voltage. Specifically, a compensation voltage c1 of the first memory cells are set, and the incremental voltage step-c1 of the first memory cells may be obtained by subtracting the compensation voltage c1 of the first memory cells from the default incremental voltage step. The compensation voltage c1 of the first memory cells within the fourth temperature range are less than the compensation voltage b1 within the second temperature range, i.e., c1<b1, and the higher the temperatures in the fourth temperature range are, the lower the compensation voltage of the first memory cells is.

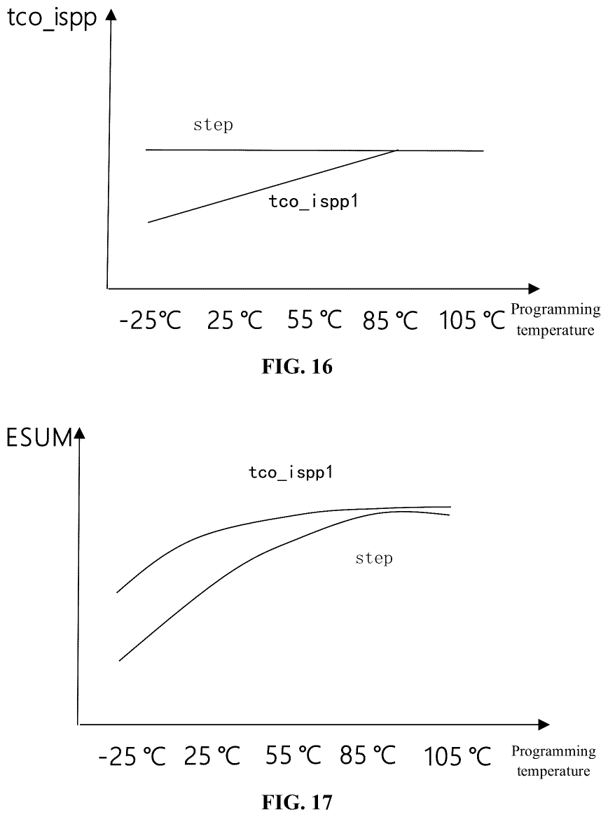

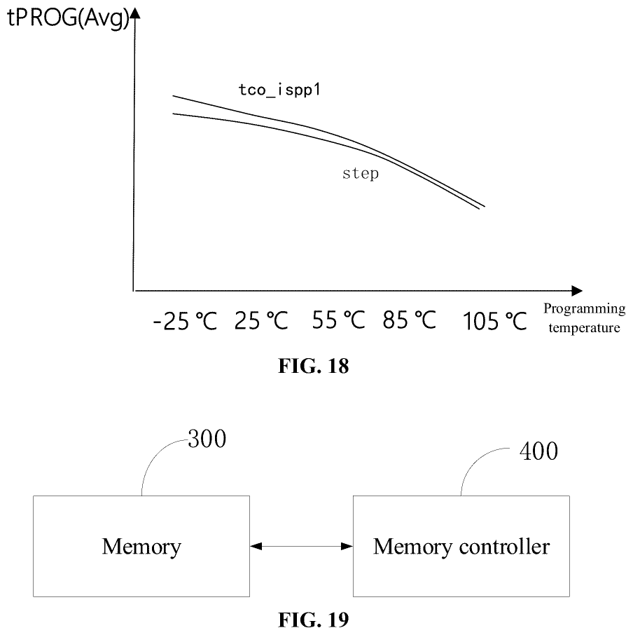

In some implementations, the higher the programming temperatures are, the smaller the compensation voltage of the memory cells is, and the larger the incremental voltage is. As shown in FIG. 16, the abscissa represents programming temperatures, and the ordinate represents incremental voltage tco_ispp. The higher the programming temperatures are, the smaller the compensation voltage of the first memory cells is, and the larger the incremental voltage tco_ispp1 is. When the programming temperatures are increased to a threshold (e.g., 90° C.), the compensation voltage of the first memory cells is 0, and the incremental voltage tco_ispp1 is the default incremental voltage step. As shown in FIGS. 17 and 18, the lower the programming temperatures are, the larger the compensation voltage of the first memory cells is, the greater the improvements of the ESUMs are, and the smaller the tPROG losses are. When the programming temperatures are high temperatures, the compensation voltage of the first memory cells is very small (or no compensation), and the tPROGs have almost no loss, i.e., the performance of the first memory cells is not affected.

In some implementations, as shown in Table 1, within the first temperature range (e.g., low temperatures), the incremental voltage of the first memory cells is step-a1, the incremental voltage of the second memory cells is step-a2, the incremental voltage of the fourth memory cells is step-a3, the incremental voltage of the third memory cells is step, and 0≤a3<a2<a1. Within the second temperature range (e.g., normal temperatures), the incremental voltage of the first memory cells is step-b1, the incremental voltage of the second memory cells is step-b2, the incremental voltage of the fourth memory cells is step-b3, the incremental voltage of the third memory cells is step, and 0≤b3<b2<b1<a1. Within the third temperature range (e.g., high temperatures), all the incremental voltages of the first memory cells, the second memory cells, the fourth memory cells and the third memory cells are steps.

TABLE 1

| | | First | Second | Fourth | Third |
|---|---|---|---|---|---|
| | Temperature | memory | memory | memory | memory |
| Temperature | range | cells | cells | cells | cells |
| Low | First temperature | step-a1 | step-a2 | step-a3 | step |
| temperatures | range | | | | |
| Normal | Second temperature | step-b1 | step-b2 | step-b3 | step |
| temperatures | range | | | | |
| High | Third temperature | step | step | step | step |
| temperatures | range | | | | |

The operation method of the memory provided by the examples described herein can perform the first temperature compensation operation on the default incremental voltage of the programming pulses to obtain the first incremental voltage of the first memory cells to be programmed when the programming temperatures are within the first temperature range, so as to perform the incremental step-pulse programming on the first memory cells according to the first incremental voltage to adjust programming speeds of the first memory cells within the first temperature range, improve read margins of the first memory cells within the first temperature range, reduce reading errors and have a smaller overall performance loss.

Accordingly, the memory provided by the examples described herein can implement the above-mentioned operation method of the memory.

As shown in FIG. 1, the memory provided by this example comprises a memory array 1 and a peripheral circuit 2 coupled to the memory array 1. The memory array 1 comprises a plurality of memory cells 12, and the peripheral circuit 2 is configured to:
acquire programming temperatures that are temperatures of memory cells to be programmed;
perform first temperature compensation operation on a default incremental voltage of programming pulses to obtain a first incremental voltage of first memory cells to be programmed when the programming temperatures are within a preset first temperature range; and
perform incremental step-pulse programming on the first memory cells according to the first incremental voltage.

Optionally, the peripheral circuit 2 is further configured to:
determine a compensation voltage of the first memory cells; and subtract the compensation voltage from the default incremental voltage to obtain the first incremental voltage of the first memory cells.

Optionally, the peripheral circuit 2 is further configured to:
perform second temperature compensation operation on the default incremental voltage to obtain a second incremental voltage of second memory cells to be programmed when the programming temperatures are within the first temperature range, a compensation voltage of the second temperature compensation operation being less than that of the first temperature compensation operation; and
perform incremental step-pulse programming on the second memory cells according to the second incremental voltage.

Optionally, the first memory cells are located at a lower portion of the memory array, and the second memory cells are located at an upper portion of the memory array.

Optionally, the peripheral circuit 2 is further configured to:
perform incremental step-pulse programming on third memory cells to be programmed according to the default incremental voltage when the programming temperatures are within the first temperature range.

Optionally, the third memory cells are located at an upper portion of the memory array.

Optionally, the peripheral circuit 2 is further configured to:
perform third temperature compensation operation on the default incremental voltage to obtain a third incremental voltage of the first memory cells when the programming temperatures are within a preset second temperature range, a compensation voltage of the third temperature compensation operation being less than that of the first temperature compensation operation, temperatures in the second temperature range being higher than those in the first temperature range; and
perform incremental step-pulse programming on the first memory cells according to the third incremental voltage.

Optionally, the peripheral circuit 2 is further configured to:
perform incremental step-pulse programming on the first memory cells according to the default incremental voltage when the programming temperatures are within a preset third temperature range, temperatures in the third temperature range being higher than those in the first temperature range.

Optionally, when the programming temperatures are within the first temperature range, the compensation voltage of the first memory cells when the number of uses is less than a preset number is less than the compensation voltage when the number of uses is greater than the preset number.

Optionally, the programming includes coarse programming and fine programming; and incremental voltages of at least one of the coarse programming and the fine programming are the first incremental voltage.

The memory provided by the examples described herein can perform the first temperature compensation operation on the default incremental voltage of the programming pulses to obtain the first incremental voltage of the first memory cells to be programmed when the programming temperatures are within the first temperature range, so as to perform the incremental step-pulse programming on the first memory cells according to the first incremental voltage to adjust programming speeds of the first memory cells within the first temperature range, improve read margins of the first memory cells within the first temperature range, reduce reading errors and have a smaller overall performance loss.

Refer to FIG. 19, which is a structural schematic diagram of a storage system provided by examples of the present application.

As shown in FIG. 19, examples described herein further provide a storage system which comprises a memory 300 and a memory controller 400, where the memory 300 is coupled with the memory controller 400, and the memory controller 400 is used to control the memory 300 to store data. The memory 300 is the memory in the above-mentioned examples and will not be described in detail here. The memory controller 400 may be a controller well-known to those skilled in the art and will not be described in detail here.

The storage system may be applied to end products, such as a computer, a television, a set-top box, a vehicle-mounted product, etc.

The examples described herein include operation methods of memories, memories, and storage systems, which can improve read margins of memory cells, reduce reading errors, and have a smaller overall performance loss.

The examples described herein provide operation methods of a memory or memories wherein the operation methods may include: acquiring programming temperatures that are temperatures of memory cells to be programmed; performing first temperature compensation operation on a default incremental voltage of programming pulses to obtain a first incremental voltage of first memory cells to be programmed when the programming temperatures are within a preset first temperature range; and performing incremental step-pulse programming on the first memory cells according to the first incremental voltage.

Optionally, performing first temperature compensation operation on a default incremental voltage of programming pulses to obtain a first incremental voltage of first memory cells to be programmed includes: determining a compensation voltage of the first memory cells; and subtracting the compensation voltage from the default incremental voltage to obtain the first incremental voltage of the first memory cells.

Optionally, the method further includes: performing second temperature compensation operation on the default incremental voltage to obtain a second incremental voltage of second memory cells to be programmed when the programming temperatures are within the first temperature range, a compensation voltage of the second temperature compensation operation being less than that of the first temperature compensation operation; and performing incremental step-pulse programming on the second memory cells according to the second incremental voltage.

Optionally, the first memory cells are located at a lower portion of a memory array, and the second memory cells are located at an upper portion of the memory array.

Optionally, the method further includes: performing incremental step-pulse programming on third memory cells to be programmed according to the default incremental voltage when the programming temperatures are within the first temperature range.

Optionally, the third memory cells are located at an upper portion of a memory array.

Optionally, the method further includes: performing third temperature compensation operation on the default incremental voltage to obtain a third incremental voltage of the first memory cells when the programming temperatures are within a preset second temperature range, a compensation voltage of the third temperature compensation operation being less than that of the first temperature compensation operation, temperatures in the second temperature range being higher than those in the first temperature range; and performing incremental step-pulse programming on the first memory cells according to the third incremental voltage.

Optionally, the method further includes: performing incremental step-pulse programming on the first memory cells according to the default incremental voltage when the programming temperatures are within a preset third temperature range, temperatures in the third temperature range being higher than those in the first temperature range.

Optionally, when the programming temperatures are within the first temperature range, the compensation voltage of the first memory cells when the number of uses is less than a preset number is less than the compensation voltage when the number of uses is greater than the preset number.

Optionally, the programming includes coarse programming and fine programming; and incremental voltages of at least one of the coarse programming and the fine programming are the first incremental voltage.

Accordingly, examples described herein further provide a memory including: a memory array; and a peripheral circuit coupled to the memory array and configured to: acquire programming temperatures that are temperatures of memory cells to be programmed; perform first temperature compensation operation on a default incremental voltage of programming pulses to obtain a first incremental voltage of first memory cells to be programmed when the programming temperatures are within a preset first temperature range; and perform incremental step-pulse programming on the first memory cells according to the first incremental voltage.

Optionally, the peripheral circuit is further configured to: determine a compensation voltage of the first memory cells; and subtract the compensation voltage from the default incremental voltage to obtain the first incremental voltage of the first memory cells.

Optionally, the peripheral circuit is further configured to: perform second temperature compensation operation on the default incremental voltage to obtain a second incremental voltage of second memory cells to be programmed when the programming temperatures are within the first temperature range, a compensation voltage of the second temperature compensation operation being less than that of the first temperature compensation operation; and perform incremental step-pulse programming on the second memory cells according to the second incremental voltage.

Optionally, the first memory cells are located at a lower portion of the memory array, and the second memory cells are located at an upper portion of the memory array.

Optionally, the peripheral circuit is further configured to: perform incremental step-pulse programming on third memory cells to be programmed according to the default incremental voltage when the programming temperatures are within the first temperature range.

Optionally, the third memory cells are located at an upper portion of the memory array.

Optionally, the peripheral circuit is further configured to: perform third temperature compensation operation on the default incremental voltage to obtain a third incremental voltage of the first memory cells when the programming temperatures are within a preset second temperature range, a compensation voltage of the third temperature compensation operation being less than that of the first temperature compensation operation, temperatures in the second temperature range being higher than those in the first temperature range; and perform incremental step-pulse programming on the first memory cells according to the third incremental voltage.

Optionally, the peripheral circuit is further configured to: perform incremental step-pulse programming on the first memory cells according to the default incremental voltage when the programming temperatures are within a preset third temperature range, temperatures in the third temperature range being higher than those in the first temperature range.

Optionally, when the programming temperatures are within the first temperature range, the compensation voltage of the first memory cells when the number of uses is less than a preset number is less than the compensation voltage when the number of uses is greater than the preset number.

Optionally, the programming includes coarse programming and fine programming; and incremental voltages of at least one of the coarse programming and the fine programming are the first incremental voltage.

Accordingly, the examples described herein further provide a storage system, comprising the above-mentioned memory, and a memory controller coupled with the memory.

Examples described herein provide an operation method of a memory, a memory, and a storage system, which can perform first temperature compensation operation on a default incremental voltage of programming pulses to obtain a first incremental voltage of first memory cells to be programmed when programming temperatures are within a first temperature range, so as to perform incremental step-pulse programming on the first memory cells according to the first incremental voltage to adjust programming speeds of the first memory cells within the first temperature range, improve read margins of the first memory cells within the first temperature range, reduce reading errors and have a smaller overall performance loss.

Although examples have been described as above, the above-mentioned examples are not used to limit the present disclosure. Those of ordinary skill in the art may make various changes and modifications without departing from the spirits and scope of the present disclosure. Therefore, the protection scope of the present disclosure shall be defined by the claims.

What is claimed is:

1. A method of operating a memory, the method comprising:
acquiring programming temperatures that are temperatures of memory cells to be programmed;
performing a first temperature compensation operation on a default incremental voltage of programming pulses to obtain a first incremental voltage of first memory cells to be programmed when the programming temperatures are within a first temperature range; and
performing incremental step-pulse programming on the first memory cells according to the first incremental voltage.

2. The operation method of the memory of claim 1, wherein performing the first temperature compensation operation on a default incremental voltage of programming pulses to obtain a first incremental voltage of first memory cells to be programmed, comprises:
determining a compensation voltage of the first memory cells; and
subtracting the compensation voltage from the default incremental voltage to obtain the first incremental voltage of the first memory cells.

3. The operation method of the memory of claim 1, further comprising:
performing a second temperature compensation operation on the default incremental voltage to obtain a second incremental voltage of second memory cells to be programmed when the programming temperatures are within the first temperature range, a compensation voltage of the second temperature compensation operation being less than that of the first temperature compensation operation; and
performing incremental step-pulse programming on the second memory cells according to the second incremental voltage.

4. The operation method of the memory of claim 3, wherein the first memory cells are located at a lower portion of a memory array, and the second memory cells are located at an upper portion of the memory array.

5. The operation method of the memory of claim 1, further comprising:
performing incremental step-pulse programming on third memory cells to be programmed according to the default incremental voltage when the programming temperatures are within the first temperature range.

6. The operation method of the memory of claim 5, wherein the third memory cells are located at an upper portion of a memory array.

7. The operation method of the memory of claim 1, further comprising:
performing a third temperature compensation operation on the default incremental voltage to obtain a third incremental voltage of the first memory cells when the programming temperatures are within a second temperature range, a compensation voltage of the third temperature compensation operation being less than that of the first temperature compensation operation, temperatures in the second temperature range being higher than those in the first temperature range; and
performing incremental step-pulse programming on the first memory cells according to the third incremental voltage.

8. The operation method of the memory of claim 1, further comprising:
performing incremental step-pulse programming on the first memory cells according to the default incremental voltage when the programming temperatures are within a third temperature range, temperatures in the third temperature range being higher than those in the first temperature range.

9. The operation method of the memory of claim 1, wherein when the programming temperatures are within the first temperature range, a compensation voltage of the first memory cells when a number of uses is less than a preset number are less than the compensation voltage when the number of uses is greater than the preset number.

10. The operation method of the memory of claim 1, wherein the programming includes coarse programming and fine programming; and incremental voltages of at least one of the coarse programming and the fine programming are the first incremental voltage.

11. A memory comprising:
a memory array; and
a peripheral circuit coupled to the memory array and configured to at least:
acquire programming temperatures that are temperatures of memory cells to be programmed;
perform a first temperature compensation operation on a default incremental voltage of programming pulses to obtain a first incremental voltage of first memory cells to be programmed when the programming temperatures are within a first temperature range; and
perform incremental step-pulse programming on the first memory cells according to the first incremental voltage.

12. The memory of claim 11, wherein the peripheral circuit is further configured to:
determine a compensation voltage of the first memory cells; and
subtract the compensation voltage from the default incremental voltage to obtain the first incremental voltage of the first memory cells.

13. The memory of claim 11, wherein the peripheral circuit is further configured to:
perform second temperature compensation operation on the default incremental voltage to obtain a second incremental voltage of second memory cells to be programmed when the programming temperatures are within the first temperature range, a compensation voltage of the second temperature compensation operation being less than that of the first temperature compensation operation; and
perform incremental step-pulse programming on the second memory cells according to the second incremental voltage.

14. The memory of claim 13, wherein the first memory cells are located at a lower portion of the memory array, and the second memory cells are located at an upper portion of the memory array.

15. The memory of claim 11, wherein the peripheral circuit is further configured to:
perform incremental step-pulse programming on third memory cells to be programmed according to the default incremental voltage when the programming temperatures are within the first temperature range, wherein the third memory cells are located at an upper portion of the memory array.

16. The memory of claim 11, wherein the peripheral circuit is further configured to:
perform a third temperature compensation operation on the default incremental voltage to obtain a third incremental voltage of the first memory cells when the programming temperatures are within a second temperature range, a compensation voltage of the third temperature compensation operation being less than that of the first temperature compensation operation, temperatures in the second temperature range being higher than those in the first temperature range; and
perform incremental step-pulse programming on the first memory cells according to the third incremental voltage.

17. The memory of claim 11, wherein the peripheral circuit is further configured to:
perform incremental step-pulse programming on the first memory cells according to the default incremental voltage when the programming temperatures are within a third temperature range, temperatures in the third temperature range being higher than those in the first temperature range.

18. The memory of claim 11, wherein when the programming temperatures are within the first temperature range, a compensation voltage of the first memory cells when a number of uses is less than a preset number is less than the compensation voltage when the number of uses is greater than the preset number.

19. The memory of claim 11, wherein the programming includes coarse programming and fine programming; and incremental voltages of at least one of the coarse programming and the fine programming are the first incremental voltage.

20. A storage system, comprising:
a memory and a memory controller coupled to the memory;
wherein the memory comprising:
a memory array; and
a peripheral circuit coupled to the memory array and configured to at least:
acquire programming temperatures that are temperatures of memory cells to be programmed;
perform a first temperature compensation operation on a default incremental voltage of programming pulses to obtain a first incremental voltage of first memory cells to be programmed when the programming temperatures are within a first temperature range; and
perform incremental step-pulse programming on the first memory cells according to the first incremental voltage.
